(19) United States
(12) Patent Application Publication
(10) Pub. No.: US 2019/0191593 A1
(43) Pub. Date: Jun. 20, 2019

(54) WATER-COOLING HEAT-DISSIPATING ASSEMBLY AND ELECTRONIC DEVICE

(71) Applicant: Lenovo (Beijing) Co., Ltd., Beijing (CN)

(72) Inventors: Shifeng WANG, Beijing (CN); Tianyu WANG, Beijing (CN)

(21) Appl. No.: 16/223,354

(22) Filed: Dec. 18, 2018

(30) Foreign Application Priority Data
Dec. 18, 2017 (CN) 201711366384.9
Feb. 1, 2018 (CN) 201810105220.9

(51) Int. Cl. H05K 7/20; F28F 27/00; G05B 15/02

(52) U.S. Cl. CPC H05K 7/20272; F28F 27/00; F28F 2265/16; H05K 7/20281; G05B 15/02; H05K 7/20254

(57) ABSTRACT

A water-cooling heat-dissipating assembly includes a water-cooling device and a water-pressure monitoring switch. The water-cooling device includes an inlet pipe, an outlet pipe, and a heat-exchange chamber connecting the inlet pipe and the outlet pipe. The water-pressure monitoring switch is located at the inlet pipe. The water-pressure monitoring switch monitors a water pressure in the water-cooling device. In response to the water pressure in the water-cooling device meeting a first preset condition, the water-pressure monitoring switch controls the inlet pipe to be closed.

### CROSS-REFERENCE TO RELATED APPLICATIONS

This application claims the priority of Chinese Patent Applications No. 201711366384.9, filed on Dec. 18, 2017, and No. 201810105220.9, filed on Feb. 1, 2018. The above enumerated patent applications are incorporated herein by reference in their entirety.

### TECHNICAL FIELD

The present disclosure relates to the field of heat dissipation technologies and, in particular, to a water-cooling heat-dissipating assembly and an electronic device having the water-cooling heat-dissipating assembly.

### BACKGROUND

With the development of science and technology, more and more components are integrated into a single electronic device. Heat dissipation of the electronic device becomes an important parameter affecting the performance of the electronic device. In a conventional electronic device, a water-cooling device is usually disposed on a chip to dissipate heat, so as to prevent the performance of the electronic device from being affected by overheating of the chip.

However, an existing water-cooling device usually has a leakage problem during an application process. The leakage of the water-cooling device can cause a short circuit in the chip, and even cause a short circuit in an entire server system. The disclosed methods and systems are directed to solve one or more problems set forth above and other problems.

### SUMMARY

In accordance with the disclosure, one aspect of the present disclosure provides a water-cooling heat-dissipating assembly. The water-cooling heat-dissipating assembly includes a water-cooling device and a water-pressure monitoring switch. The water-cooling device includes an inlet pipe, an outlet pipe, and a heat-exchange chamber connecting (or coupled to) the inlet pipe and the outlet pipe. The water-pressure monitoring switch is located at the inlet pipe. The water-pressure monitoring switch monitors a water pressure in the water-cooling device. In response to the water pressure in the water-cooling device meeting a first preset condition, the water-pressure monitoring switch controls the inlet pipe to be closed.

In accordance with the disclosure, another aspect of the present disclosure provides an electronic device. The electronic device includes a mainboard, a water-cooling heat-dissipating assembly. The water-cooling heat-dissipating assembly can cool the mainboard. The water-cooling heat dissipating assembly includes a water-cooling device and a water-pressure monitoring switch. The water-cooling device includes an inlet pipe, an outlet pipe, and a heat-exchange chamber connecting the inlet pipe and the outlet pipe. The water-pressure monitoring switch is located at the inlet pipe. The water-pressure monitoring switch monitors a water pressure in the water-cooling device. In response to the water pressure in the water-cooling device meeting a first preset condition, the water-pressure monitoring switch controls the inlet pipe to be closed.

### DESCRIPTION OF THE DRAWINGS

To more clearly illustrate embodiments of the present disclosure, this section briefly describes drawings illustrating embodiments of the present disclosure. Obviously, the drawings described below merely show some embodiments of the present disclosure. Those skilled in the art can obtain other drawings according to the drawings provide in the present disclosure without creative efforts.

FIG. 1 is a structural diagram of a water-cooling heat-dissipating assembly according to disclosed embodiments of the present disclosure;

FIG. 2 is a structural diagram of a water-cooling heat-dissipating assembly according to disclosed embodiments of the present disclosure; and

FIG. 3 is a structural diagram of an electronic device according to disclosed embodiments of the present disclosure.

### DETAILED DESCRIPTION

The followings describe technical solutions according to embodiments of the present disclosure with reference to the accompany drawings. Obviously, the embodiments described below are merely a part of, not all of embodiments of the present disclosure. Other embodiment may be obtained by those skilled in the art based on the embodiments of the present disclosure without creative efforts, which shall fall within the scope of the present disclosure.

In the following description, specific details are set forth in order to provide understanding of the present disclosure, but the present disclosure can be implemented in other ways than those described herein. Those skilled in the art can make variations without departing from the scope of the disclosure. The disclosure is not limited by the specific embodiments disclosed below.

As described in the technical background section, an existing water-cooling device usually has a leakage problem during an application process. The leakage of the water-cooling device can cause a short circuit in the chip, or even cause a short circuit in an entire server system.

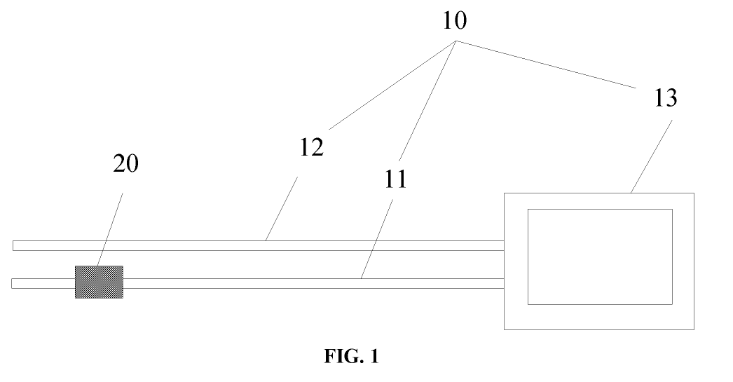

To solve the above problem, the present disclosure provides an improved water-cooling heat-dissipating assembly. As shown in FIG. 1, the water-cooling heat-dissipating assembly includes a water-cooling device 10, and a water-pressure monitoring switch 20. Other components may also be included.

The water-cooling device 10 includes an inlet pipet 11, an outlet pipe 12, and a heat-exchange chamber 13. The heat-exchange chamber 13 connects the inlet pipe 11 with the outlet pipe 12. The water-pressure monitoring switch 20 is disposed on the inlet pipe 11 and can monitor the water pressure in the water-cooling device 10. In response to the water pressure in the water-cooling device 10 in a change, e.g., meeting a first preset condition, the water-pressure monitoring switch 20 can close the inlet pipe 11 to prevent water from entering the water-cooling device 10.

When the water-cooling heat-dissipating assembly is in operation, the cold water enters the heat-exchange chamber 13 from the inlet pipe 11 of the water-cooling device 10, absorbs heat dissipated by hot elements (i.e., elements that need to be cooled) arranged near to the heat-exchange chamber 13, and the heated water then exits the water-cooling device 10 through the outlet pipe 12. In this way, cooling of the hot elements can be achieved.

It should be noted that when there is no leakage in the water-cooling device 10, the water pressures of different positions in the water-cooling device 10 are the same constant value. That is, when the water pressure in the water-cooling device is the constant value, water pressure of the inlet pipe 11 is also the constant value. However, when the water-cooling device 10 has a leakage, the water pressure of the water-cooling device can change significantly. Thus, in the water-cooling heat-dissipating assembly consistent with the present disclosure, through the water-pressure monitoring switch 20, the water pressure in the water-cooling device 10 can be monitored; and in response to the water pressure in the water-cooling device 10 meeting the first preset condition, the inlet pipe 11 can be controlled to be closed. As such, it is possible to avoid water continuing entering the water-cooling device 10 causing the water infiltrating into the hot elements or even affecting the normal operation of the hot elements.

In some embodiments of the present disclosure, the water-pressure monitoring switch 20 can monitor the water pressure in the water-cooling device 10 in a real-time manner, such that the leakage of the water-cooling device 10 can be detected in real time. In some other embodiments, the water-pressure monitoring switch 20 can monitor the water pressure in the water-cooling device 10 per a preset time interval to reduce a power consumption of the water-pressure monitoring switch 20. Of course, operation manners of the water-pressure monitoring switch are not limited by the present disclosure and can be determined based on actual conditions.

In some embodiments, water can be used as a heat-exchange liquid for cooling in the water-cooling heat-dissipating assembly. The present disclosure does not limit the heat-exchange liquid used for cooling in the water-cooling heat dissipating assembly. The heat-exchange liquid can flow in the water-cooling heat-dissipating assembly. In some other embodiments, liquids, such as water, ethylene glycol, etc., can be used as the heat-exchange liquid. Correspondingly, the water-pressure monitoring switch can monitor the pressure of the heat-exchange liquid in the water-cooling device 10. In response to the pressure of the heat-exchange liquid in the water-cooling device 10 meeting a first preset condition, the water-pressure monitoring switch 20 can close the inlet pipe 11.

Thus, when the water-cooling heat-dissipating assembly consistent with the present disclosure is in operation, it can be detected in time when the leakage occurs. In addition, when the leakage occurs, the inlet pipe 11 is closed, so as to avoid the leakage of the water-cooling device causing a short circuit in the chip, or even causing a short circuit in an entire server system.

In some embodiments of the present disclosure, the water-pressure monitoring switch 20 can further include a pressure gauge monitoring the water pressure in the water-cooling device 10, a valve controlling opening and closing of the inlet pipe 11, and a controller. In response to the water pressure monitored by the water-pressure monitoring switch meeting the first preset condition, the controller can control the valve to be closed, so as to control the inlet pipe 11 to be closed.

In some embodiments of the present disclosure, when the water-cooling device 10 is working normally, the water pressure in the inlet pipe 11 and the water pressure the outlet pipe 12 are equal. When a leakage of the water-cooling device 10 occurs, the water pressure in the inlet pipe 11 and the water pressure the outlet pipe 12 can change significantly. Therefore, in some other embodiments, the pressure gauge may not be integrated with the valve. The pressure gauge may be disposed on the inlet pipe 11 or the outlet pipe 12, which is not limited by the present disclosure and can be determined according to actual conditions.

In some embodiments of the present disclosure, the pressure gauge can monitor the water pressure in the water-cooling device 10 by monitoring the water pressure at a position at the water-cooling device 10. In response to the water pressure monitored by the water-pressure monitoring switch meeting the first preset condition, the controller can control the valve to be closed, so as to control the inlet pipe 11 to be closed.

In some embodiments, the pressure gauge can be disposed at one or more preset position at the inlet pipe, or at one or more preset position at the outlet pipe, which is not limited by the present disclosure and can be determined by the actual conditions.

Further, the preset position at the inlet pipe and/or the outlet pipe may be a position of a range of pipeline at the inlet pipe and/or the outlet pipe where rupture or pipe distortion of the pipeline is prone to occur. The rupture or pipe distortion of the pipe line may be caused by, e.g., the pipeline being narrowed due to accumulation of residues, scale, etc. For example, the preset position can be set in an area near a corner of the inlet pipe and/or the outlet pipe, or in a nearby area where the piper diameter of the inlet pipe and/or the outlet pipe changes (e.g., where the pipelines are split or mixed). It is more likely that flow anomalies occur at the above pipeline areas. Therefore, the pressure gauge monitors pressure changes at the preset positions in the above pipeline areas, so as to reflect the flow anomalies in the water-cooling heat-dissipating assembly sensitively and efficiently.

Therefore, using the water-cooling heat-dissipating assembly consistent with the present disclosure, when the flow anomalies occurs in the water-cooling heat-dissipating assembly, the inlet pipe 11 can be timely closed. As such, the liquid in the water-cooling heat-dissipating assembly can be shut down in real time, so as to gain certain amount of time for further emergency treatment. It is possible to avoid the leakage of the water-cooling device causing a short circuit in the chip or even causing a short circuit in an entire server system. In this way, heat-dissipating requirement of the normal operation of the electronic device can be satisfied, and the operational safety of the electronic device can also be improved.

When the water-cooling heat-dissipating assembly is in operation, the inlet pipe 11 can input external cold water into the heat-exchange chamber 13, and the outlet pipe 12 can output hot water from the heat exchange chamber 13. When the leakage occurs in the water-cooling device 10, and the position of leakage is uncertain, in order to minimize the possibility of short circuit caused by the leakage of the water-cooling device 10, the valve can be disposed at the inlet pipe 11.

When the valve is disposed before the position of leakage (i.e., when the valve is passed by the flow of the cool water earlier than the position of leakage), the short circuit caused by leakage of the water-cooling device can be avoided. Therefore, in some embodiments, the valve can be disposed closer to the inlet of the inlet pipe 11 and distal to the side of the heat-exchange chamber 13. The water-pressure monitoring switch 20 can also be disposed at the inlet pipe 11, when the pressure gauge is integrated with the valve.

In some embodiments of the present disclosure, the first preset condition may include that the difference between the water pressure of the water-cooling device 10 and the preset water pressure exceeds a preset value. By setting the preset condition, it is possible to timely detect the abnormal water pressure of the water-cooling heat-dissipating assembly, and it is possible to avoid maloperation when the water pressure in the water-cooling heat-dissipating assembly fluctuates due to certain factors.

In some embodiments, the preset value can be a preset percentage of the preset water pressure, e.g., within 5% to 10% of the preset water pressure (including endpoint values). When the difference between the water pressure of the water-cooling device 10 and the preset water pressure exceeds the preset percentage of the preset water pressure, the water pressure of the water-cooling device 10 meets the first preset condition, and the inlet pipe 11 is controlled to be closed. When the difference between the water pressure of the water-cooling device 10 and the preset water pressure is within the present percentage of the preset water pressure, the water pressure of the water-cooling device 10 does not meet the first preset condition, the inlet pipe 11 can be kept open.

In some embodiments, the preset water pressure can be the water pressure of inlet pipe 11 (or the outlet pipe 12) when the water-cooling device 10 is operating normally. The preset water pressure is not limited by the present disclosure and can be determined according to actual conditions.

In some other embodiments, the first preset condition may include that the water pressure of the water-cooling device 10 is lower than the preset water pressure, which is not limited by the present disclosure can be determined by actual conditions.

In some embodiments, the water-pressure monitoring switch 20 can send a prompt information in response to the water pressure of the water-cooling device 10 meeting the first preset condition, to indicate that the water-cooling device 10 is leaking.

In some embodiments, the inlet pipe 11 and the outlet pipe 12 may be connected by a water storage device 30. As described here, the materials, shapes, etc., of the water storage device 30 are not limited by the present disclosure. In some other embodiments, the water outlet 12 may not be connected with the inlet pipe 11, which can be determined according to actual conditions.

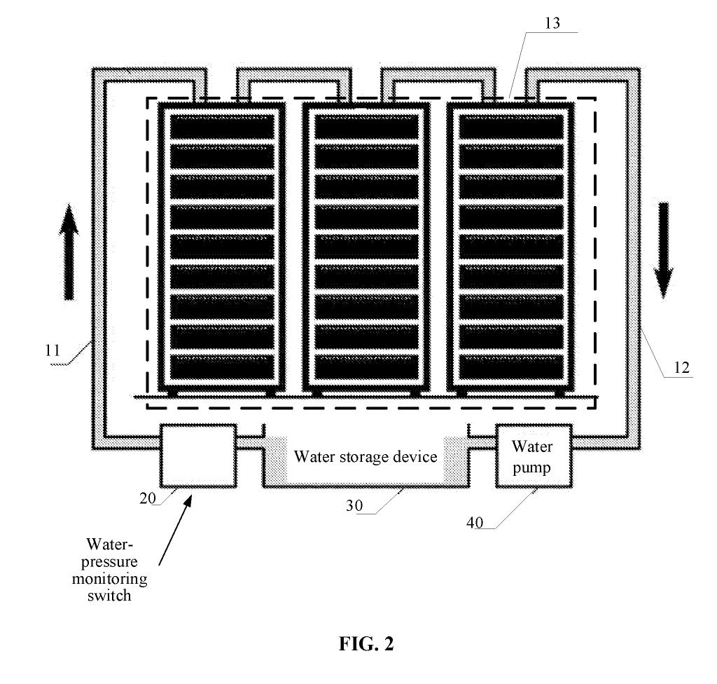

In some embodiments, as shown in FIG. 2, a water pump 40 is further disposed on the inlet pipe and/or the outlet pipe of the water-cooling heat-dissipating assembly. The water pump 40 can maintain the water pressure inside the pipeline (the inlet pipe 11 and/or the outlet pipe 12) as a preset value.

In some embodiments, the water pump 40 can maintain a pressure inside the pipeline as a negative pressure (i.e., lower than ambient atmospheric pressure). Thus, when the water-cooling heat-dissipating assembly is in operation, the water pump 40 can maintain the pressure inside the pipeline lower than the ambient atmospheric pressure. Such that, when the pipeline where the water pump 40 is located partially ruptures, during a short time, because of the pressure difference between the pressures inside and outside the pipeline where the water pump 40 is located, ambient air can be filled into the pipeline to prevent the liquid inside the pipeline from leaking out. Therefore, it is possible to effectively prevent the short-circuit or losing data, etc., caused by liquid leaking out from the water-cooling device 10.

In addition, the water-pressure monitoring switch 20 can monitor the pressure change caused by local rupture in the water-cooling device 10 (including the inlet pipe 11 and/or the outlet pipe 12). In response to the water pressure inside the water-cooling device 10 meeting the first preset condition, the water-pressure monitoring switch 20 control the inlet pipe 11 to be closed. As such, the liquid flow in the water-cooling device 10 can be blocked, thereby providing a certain protection function to avoid the anomalies of the inlet pipe 11 and/or the outlet pipe 12, and reducing the risk caused by the liquid leakage in the water-cooling device.

Moreover, in the water-cooling heat-dissipating assembly consistent with the present disclosure, after the inlet pipe 11 is closed by the valve to block the liquid flowing inside the water-cooling device 10, the water pump 40 can continue to work until the liquid in the water-cooling device 10 is drained. As such, the electronic device can have a certain protection function to avoid the anomalies of the inlet pipe 11 and/or the outlet pipe 12, thereby reducing the risk caused by the liquid leakage in the water-cooling device.

In some embodiments of the present disclosure, the water pump 40 can also maintain the pressure inside the pipeline equal to or greater than the ambient atmospheric pressure. In this way, when the leakage occurs in the water-cooling device 10, the water pressure in the inlet pipe and/or the outlet pipe may undergo abnormal changes (i.e., meeting the first preset condition). The water-pressure monitoring switch 20 can detect the abnormal changes and control the inlet pipe 11 to be closed, so as to prevent the water from continuing flowing from the inlet pipe 11 into the heat-exchange chamber 13, thereby gaining some time for further emergency treatment. It is possible to prevent the leakage of the water-cooling device to cause a short circuit in the chip, or even to cause a short circuit in an entire server system.

In some embodiments, in order to facilitate the water pump 40 to continue to work until the liquid in the water-cooling device 10 is drained, after the inlet pipe 11 is closed by the valve to block the liquid flowing inside the water-cooling device 10, the water pump 40 can be disposed at the outlet pipe 12 as shown in FIG. 2. The location of the water pump 40 is not limited by the present disclosure and can be determined by the actual conditions.

The pressure gauge can monitor the water pressure in the water-cooling device 10 by monitoring the water pressure at a preset position of the water-cooling device 10. In some embodiments, the pressure gauge can be disposed at one or more preset position at the inlet pipe, or at one or more preset position at the outlet pipe, which is not limited by the present disclosure and can be determined by the actual conditions. Further, the preset position at the inlet pipe and/or the outlet pipe may be a position of a range of pipeline at the inlet pipe and/or the outlet pipe where rupture or pipe distortion of the pipeline is prone to occur. The rupture or pipe distortion of the pipe line may be caused by, e.g., the pipeline being narrowed due to accumulation of residues, scale, etc. For example, the preset position can be set in an area near a corner of the inlet pipe and/or the outlet pipe, or in a nearby area where a piper diameter of the inlet pipe and/or the outlet pipe changes (e.g., where the pipelines are split or mixed). It is more possible that flow anomalies occur at the above pipeline areas. As shown in FIG. 2, the preset position can be set in an upstream or downstream of a corner region in the water-cooling heat-dissipating assembly, according to a pressure variation direction at each corner region of the inlet pipe 11 and outlet pipe 12, or the location of the water pump 40.

As shown in FIG. 2, if the water pump 40 is in the downstream of the flow, when any of the corner regions of the inlet pipe 11 and/or the outlet pipe 12 is broken, the flow in the downstream direction can be controlled by the water pump 40 and can be relatively stable in a short time; however, the flow in the upstream direction can be easily affected. The water-pressure monitoring switch 20 can be disposed in the upstream of each corner region of the inlet pipe 11 and/or the outlet pipe 12, so as to timely prevent the liquid from flowing in the inlet pipe 11 and/or the outlet pipe 12 when water-cooling heat-dissipating assembly leaks.

In some embodiments, the water-cooling heat-dissipating assembly may include one water-pressure monitoring switch 20. In some other embodiments, the water-cooling heat-dissipating assembly may include multiple water-pressure monitoring switches 20. For example, when the pipelines of the inlet pipe 11 and/or the outlet pipe 12 are relatively complex, the water-pressure monitoring switches 20 may be respectively disposed at different positions of the inlet pipe 11 and/or the outlet pipe 12, to timely and effectively monitor the water pressure inside the water-cooling heat-dissipating assembly.

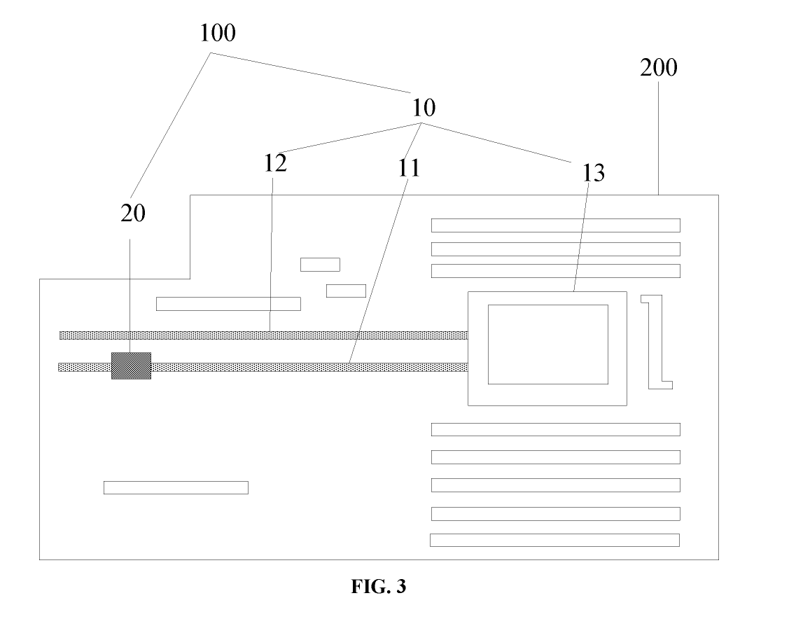

Another aspect of the present disclosure provides an electronic device. As shown in FIG. 3, the electronic device includes a water-cooling device 100 and a mainboard (or motherboard) 200. The water-cooling heat-dissipating assembly 100 can cool the mainboard 200. The water-cooling heat-dissipating assembly 100 can be a water-cooling heat-dissipating assembly consistent with the present disclosure, e.g., the water-cooling heat-dissipating assembly described in above embodiments of the present disclosure. The water-cooling heat-dissipating assembly 100 includes a water-cooling device 10, and a water-pressure monitoring switch 20. The water-cooling device 10 includes an inlet pipe 11, an outlet pipe 12 and a heat-exchange chamber 13. For detailed information of the water-cooling heat-dissipating assembly, reference can be made to the above embodiments, and details are not repeated here.

In some embodiments, the mainboard 200 may include various types of chips, such as a processor, a memory, a display card, a network card, and/or a circuit board, etc., which is not limited by the present disclosure, and can be determined by actual conditions.

In some embodiments, the water-cooling heat-dissipating assembly 100 can be encapsulated inside the electronic device. To dissipate heat, liquid flows into the heat-exchange chamber 13 of the water-cooling heat-dissipating assembly 100 through the inlet pipe 11 to cool the mainboard 200 by taking way the heat generated by the mainboard 200. After the liquid flows out from the outlet pipe 12, the liquid can be cooled in an area, e.g., near the fan or at an air outlet, etc., to release the heat generated by the mainboard 200 to an external environment.

In some other embodiments of the present disclosure, a part of the water-cooling heat-dissipating assembly 200 is encapsulated inside the electronic device. For example, the inlet pipe 11 can be located inside the electronic device and transports the cool liquid into the heat-exchange chamber 13. The cool liquid can absorb the heat generated by the mainboard 200 to cool the mainboard of the electronic device. An end of the outlet pipe 12 that is distal from the heat-exchange chamber 13 (e.g., the exit of the outlet pipe) can be located outside the electronic device, to dissipate the absorbed heat in another heat-dissipating device (e.g., a cooling tower, a cooling water tank), or to dissipate the absorbed heat by exchanging heat with the ambient atmosphere. As such, the heat generated by the mainboard 200 can be released to the external environment of the electronic device.

In some embodiments, the inlet pipe 11 can be connected with the outlet pipe 12, that is, the inlet pipe 11, the heat-exchange chamber 13, and the outlet pipe 12 form a closed loop to effectively recycle liquid flowing in the water-cooling heat-dissipating assembly. Specifically, the liquid in the inlet pipe 11 enters the heat-exchange chamber 13 to absorb heat from the mainboard, and takes away the heat generated by the mainboard 200, flows out through the outlet pipe 12 to release the absorbed heat in a heat-dissipating environment (e.g., the cooling water tank, the air outlet, the area near the fan) of the electronic device, and flows into the inlet pipe 11 again.

In some other embodiments, the water-cooling heat-dissipating assembly can be an open heat-dissipating device, that is, the inlet pipe 11 and the outlet pipe 12 are not connected. For example, the liquid in the inlet pipe 11 enters the heat-exchange chamber 13 to absorb heat from the mainboard 200, takes away the heat generated by the mainboard 200, and flows out through the outlet pipe 12, but not flows into the inlet pipe 11 again.

In some embodiments, the water-cooling heat-dissipating assembly 100 can send a prompt instruction in response to the water pressure of the water-cooling device 10 meeting a first preset condition. The prompt instruction is to indicate the mainboard 200 that the water-cooling heat-dissipating assembly 100 stops working.

In some embodiments, the mainboard 200 can start an emergency protection mechanism in response to the prompt instruction. The emergency protection mechanism is to prevent the mainboard 200 from operation abnormally due to being over heated. Specifically, the emergency protection mechanism of the mainboard 200 includes, but not limited to, reducing power consumption, entering a sleep or standby state, or starting a backup heat-dissipating method.

In some embodiments, the water-cooling heat-dissipating assembly 100 and the mainboard 200 can be coupled, e.g., communicationally connected by a cable. In some other embodiments, the water-cooling heat-dissipating assembly 100 and the mainboard 200 can be coupled, e.g., communicatively connected by other wireless or wired methods, which is not limited by the present disclosure and can be determined by actual conditions.

In some embodiments of the present disclosure, the electronic device may be a tablet personal computer (PC), a smart phone, a mobile phone, a video phone, an e-book reader, a desktop PC, a laptop PC, a netbook computer, a workstation, a server, a personal digital assistant (PDAs), a portable multimedia player (PMPs), a MPEG-1 audio layer-3 (MP3) player, a mobile medical device, a camera and a wearable device, etc.

Further, the wearable device may include one of the following types: a jewelry type (e.g., watches, rings, bracelets, ankle rings, a necklace, glasses, contact lens or head mounted devices (HMDs)), a clothing or apparel integration type (e.g., electronic clothing), a body attachment type (e.g., skin stickers or tattoos), and a biological implant type (e.g., implantable circuits).

In some other embodiments of the disclosure, the electronic device may be one of household appliances. A smart home device in the household appliances may include one of the followings: a television, a digital video disc (DVD) player, an audio device, a refrigerator, an air conditioner, a vacuum cleaner, an oven, a microwave oven, a washing machine, an air purifier, a set top box, a home automatic control panel, a security control panel, a TV box (e.g., Samsung HomeSync™, Apple TV™ or Google TV™), a game console (e.g., Xbox™ and PlayStation™), an electronic dictionary, an electronic key, a video camera, an electronic photo frame, etc.

In further other embodiments of the present disclosure, the electronic device may include one of the followings: various medical devices (e.g., various portable medical measuring devices, such as blood-glucose monitoring devices, heart-rate monitoring devices, blood-pressure measuring devices, body-temperature measuring devices, etc., magnetic resonance angiography (MRA), magnetic resonance imaging (MM), computed tomography (CT) and ultrasound scanners), navigation devices, global positioning system (GPS) receivers, event data recorders (EDR), flight data recorder (FDR), vehicle infotainment equipment, marine electronic devices (e.g., marine navigation devices and compasses), avionics, safety equipment, vehicle head units, industrial or domestic robots, automated automatic teller machines (ATMs), sale points of a store or internet of things (IoT) (e.g., light bulbs, various sensors, electricity meters or gas meters, sprinkler equipment, fire alarms, thermostats, street lights, toasters, sports facilities, hot water tanks, heaters, boilers, etc.).

In further other embodiments of the present disclosure, the electronic device may include one of following: a furniture or a part of a building/structure, an electronic board, an electronic signature receiving device, a projector, and one of various measuring instruments (e.g., a water meter, an electric meter, a gas meter and a radio wave meter).

In some embodiments of the present disclosure, the electronic device may be a combination of one or more of the foregoing various devices. The electronic device consistent with the present disclosure may be a rigid electronic device, a flexible electronic device, or another novel electronic device, which is not limited by the present disclosure and may be determined according to actual conditions.

Thus, the water-cooling heat-dissipating assembly 100 consistent with the present disclosure can monitor the water pressure in the water-cooling device 10 through the water-pressure monitoring switch 20, and in response to the water pressure in the water-cooling device 10 meeting the first preset condition, the inlet pipe 11 is controlled to be closed, so that the leakage of the water-cooling heat-dissipating assembly 100 can be timely detected. In addition, when the leakage occurs, the inlet pipe 11 is closed, so as to avoid the leakage of the water-cooling device causing a short circuit in the chip, or even causing a short circuit in an entire server system.

Embodiments of the present specification are described in a progressive manner, and each embodiment focuses on differences from other embodiments, and the same or similar parts between the various embodiments may be referred to each other.

The above description of the disclosed embodiments enables those skilled in the art to implement or use the disclosure. Various modifications to these disclosed embodiments are obvious to those skilled in the art, and the general principles defined herein may be implemented in other embodiments without departing from the spirit or scope of the disclosure. Therefore, the present disclosure is not limited to the embodiments disclosed herein, but the scope of the disclosure is to be accorded as the widest range consistent with the principles and novel features disclosed herein.

What is claimed is:

1. A water-cooling heat-dissipating assembly, comprising:
a water-cooling device including an inlet pipe, an outlet pipe, and a heat-exchange chamber coupled to the inlet pipe and the outlet pipe; and
a water-pressure monitoring switch located at the inlet pipe, wherein the water-pressure monitoring switch is configured to monitor a water pressure in the water-cooling device and, in response to a change in the water pressure in the water-cooling device, to close the inlet pipe to prevent water from entering into the water-cooling device.

2. The water-cooling heat-dissipating assembly according to claim 1, wherein the water-pressure monitoring switch comprises:
a pressure gauge configured to monitor the water pressure of the water-cooling device;
a valve configured to open and close the inlet pipe to allow water to or prevent water from entering into the water-cooling device respectively; and
a controller configured to close the inlet pipe in response to the pressure gauge detecting a change in the water pressure of the water-cooling device.

3. The water-cooling heat-dissipating assembly according to claim 2, wherein a change in the water pressure of the water-cooling device includes:
a difference between the water pressure in the water-cooling device and a preset water pressure exceeding a preset value.

4. The water-cooling heat-dissipating assembly according to claim 3, wherein:
the preset value is a preset percentage of the preset water pressure, and the preset percentage is within 10%.

5. The water-cooling heat-dissipating assembly according to claim 1, wherein:
the water-pressure monitoring switch is further configured to send a prompt information in response to a change in the water pressure in the water-cooling device.

6. An electronic device, comprising:
a motherboard; and
a water-cooling heat-dissipating assembly cooling the motherboard, wherein the water-cooling heat dissipating assembly includes:
a water-cooling device including an inlet pipe, an outlet pipe, and a heat-exchange chamber coupled to the inlet pipe and the outlet pipe; and
a water-pressure monitoring switch located at the inlet pipe, and configured to monitor a water pressure in the water-cooling device, and in response to a change in the water pressure in the water-cooling device, to close the inlet pipe to prevent water from entering into the water-cooling device.

7. The electronic device according to claim 6, wherein the water-pressure monitoring switch comprises:
a pressure gauge configured to monitor the water pressure of the water-cooling device;
a valve controlling configured to open and close the inlet pipe to allow water to or prevent water from entering into the water-cooling device respectively; and
a controller configured to close the inlet pipe in response to the pressure gauge detecting a change in the water pressure of the water-cooling device.

8. The electronic device according to claim 7, wherein the first preset condition comprises:
a difference between the water pressure in the water-cooling device and a preset water pressure exceeding a preset value.

9. The electronic device according to claim 8, wherein:
the preset value is a preset percentage of the preset water pressure, and the preset percentage is within 10%.

10. The electronic device according to claim 6, wherein:
the water-pressure monitoring switch is further configured to send a prompt information in response to a change in the water pressure in the water-cooling device.

11. The electronic device according to claim 6, wherein:
the water-cooling heat-dissipating assembly is configured to send a prompt instruction in response to a change in the water pressure in the water-cooling device, and the prompt instruction is to inform the motherboard that the water-cooling device has stopped working.

12. The electronic device according to claim 11, wherein:
the motherboard is configured to activate an emergency protection mechanism in response to the prompt instruction, and the emergency protection mechanism is to prevent the motherboard from overheating.

13. The electronic device according to claim 6, wherein:
the water-cooling device is in coupled to the motherboard via a cable.
